(19) United States
(12) Patent Application Publication
(10) Pub. No.: US 2025/0189583 A1
(43) Pub. Date: Jun. 12, 2025

(54) SEQUENTIAL DIAGNOSIS RESET

(71) Applicant: Infineon Technologies AG, Neubiberg (DE)

(72) Inventors: Robert ILLING, Finkenstein am Faaker See (AT); Alexander MAYER, Treffen (AT)

(21) Appl. No.: 18/937,808

(22) Filed: Nov. 5, 2024

(30) Foreign Application Priority Data
Dec. 12, 2023 (DE) 102023134850.7

(51) Int. Cl. G01R 31/327; G01R 31/00

(52) U.S. Cl. CPC G01R 31/327; G01R 31/007

(57) ABSTRACT

A method for performing a sequential diagnosis in a power network is presented. The method comprises:
a) sending a diagnosis control signal from a controller to a power switch for starting the sequential diagnosis at an initial diagnosis state of the power switch and using timeouts of the diagnosis control signal for changing a present diagnosis state of the power switch;
b) if a timeout matches a predetermined time interval, continuing the sequential diagnosis by going on to a subsequent diagnosis state of the present diagnosis state; and
c) if a timeout exceeds a predetermined time threshold, resetting the sequential diagnosis by restarting at the initial diagnosis state.

Further, a power switch is presented.

### TECHNICAL FIELD

The present disclosure relates to a method for performing a sequential diagnosis in a power network and a power network.

### BACKGROUND

Decentralized, dependable automotive power distribution typically demands reliable solutions for wire harness protection. Thus, melting fuses may increasingly be replaced by intelligent protected power switches. Such power switches allow the development of distributed power network architectures which are for instance required for autonomous driving technologies. Such power switches further typically offer measures for diagnosis, such as by providing a current sense signal which may for instance indicate an overcurrent. In such an event, the power switches may be then opened, specifically for wire harness protection.

### SUMMARY

In a first aspect, a method for performing a sequential diagnosis in a power network is presented. The method comprises:
a) sending a diagnosis control signal from a controller to a power switch for starting the sequential diagnosis at an initial diagnosis state of the power switch and using timeouts of the diagnosis control signal for changing a present diagnosis state of the power switch;
b) if a timeout matches a predetermined time interval, continuing the sequential diagnosis by going on to a subsequent diagnosis state of the present diagnosis state; and
c) if a timeout exceeds a predetermined time threshold, resetting the sequential diagnosis by restarting at the initial diagnosis state.

In a further aspect, a power network is presented. The power network comprises at least a power switch for switching a load and a controller for controlling the power switch. The controller is configured for sending a diagnosis control signal to the power switch for starting a sequential diagnosis at an initial diagnosis state of the power switch. The controller is further configured for using timeouts of the diagnosis control signal for changing a present diagnosis state of the power switch. The power switch is configured for, if a timeout matches a predetermined time interval, continuing the sequential diagnosis by going on to a subsequent diagnosis state of the present diagnosis state. The power switch is further configured for, if a timeout exceeds a predetermined time threshold, resetting the sequential diagnosis by restarting at the initial diagnosis state.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates an exemplary embodiment of a distributed automotive power network;

FIG. 2 illustrates a circuit diagram of an exemplary embodiment of a power network;

FIG. 3 illustrates a flow chart of an exemplary embodiment of a method for performing a sequential diagnosis in a power network; and

FIG. 4 illustrates a further flow chart indicating an exemplary sequence of diagnosis states in a sequential diagnosis.

### DETAILED DESCRIPTION

In a first aspect, a method for performing a sequential diagnosis in a power network is presented. The term “power network” as generally used herein is a broad term and is to be given its ordinary and customary meaning to a person of ordinary skill in the art and is not to be limited to a special or customized meaning. The power network may be an at least partially interconnected system configured for transmitting or specifically for distributing electrical power or electrical energy. The power network may comprise at least one of: a power supply, e.g. a battery; a transmission line, e.g. a wire or a trace; a load; a power distribution device; a monitoring device, e.g. a sensor. The load may for instance comprise a motor. The power distribution device may specifically comprise a power switch and/or a controller. Specifically, as will also be outlined in further detail below, the power network comprises at least one power switch for switching a load and a controller for controlling the power switch. The power network may be an isolated power network. Thus, the power network may not be connected to further power networks. The power network may be an automotive power network. The power network may be a distributed power network. Specifically, the power network may be a distributed automotive power network. Thus, the power network may specifically be configured for distributing electrical power in an automotive application, such as to different parts or components of a car. In other words, the method may be performed in an automotive power network, specifically in a distributed automotive power network. Thus, the method and/or the power network may be used for an automotive application. Generally, other options than those which are exemplarily listed herein may also be feasible.

The term “sequential diagnosis” as generally used herein is a broad term and is to be given its ordinary and customary meaning to a person of ordinary skill in the art and is not to be limited to a special or customized meaning. The sequential diagnosis may be a step-by-step process or a step-by-step procedure for identifying faults or failure events in a system, specifically in a power network. Specifically, the sequential diagnosis may be a step-by-step process for identifying a failure event in at least one component of the power network. The failure event may for instance be or comprise an overcurrent. The sequential diagnosis may comprise measuring or sensing at least one physical property, e.g. a current. The sequential diagnosis may further comprise evaluating the physical property. As an example, the sequential diagnosis may comprise deriving a further physical property therefrom, e.g. an energy or a temperature. As a further example, the sequential diagnosis may comprise comparing the physical property to a threshold, e.g. a predetermined overcurrent value. Thus, the sequential diagnosis may comprise different steps or diagnosis states as will also be described in further detail below. As indicated, the sequential diagnosis may specifically be performed in a step-by-step fashion or in other words sequentially. Thus, the sequential diagnosis may comprise stepping through or sweeping through a plurality of diagnosis states. However, jumping between different diagnosis states may also be possible. Specifically, the sequential diagnosis may also allow a reset to an initial step or diagnosis state.

In a step a), the method comprises sending a diagnosis control signal from a controller to a power switch for starting the sequential diagnosis at an initial diagnosis state of the power switch. Further, the method comprises using timeouts of the diagnosis control signal for changing a present diagnosis state of the power switch. The term “controller” as generally used herein is a broad term and is to be given its ordinary and customary meaning to a person of ordinary skill in the art and is not to be limited to a special or customized meaning. The controller may be a device configured for observing or regulating or operating or managing at least one further entity. The controller may be or may comprise an electronic device or more specifically a computing device. Thus, the controller may be or may comprise at least one electronic circuit, specifically an integrated circuit. The controller may comprise at least one processor, e.g. a central processing unit. The controller may comprise at least one peripheral, e.g. an input/output interface or a memory. The controller may specifically be microcontroller. Thus, the controller may be embedded in the power network. As said, the power network may specifically be a distributed automotive power network. Thus, the controller may be a zone controller or a central controller. A zone controller may be configured for controlling at least one spatial zone or functional zone of the power network. The zone may for instance be a front of a car or a back of a car. A central controller may be configured for controlling the entire power network. Other options may generally also be feasible.

The term “power switch” as generally used herein is a broad term and is to be given its ordinary and customary meaning to a person of ordinary skill in the art and is not to be limited to a special or customized meaning. The power switch may be or may comprise an electronic component configured for controlling electric power flow in an electronic circuit. The power switch may be configured for turning on or off a power supply to a further device, specifically to a load. In a power network, the power switch may be configured for connecting or disconnecting different parts of the power network. The power switch may be or may comprise at least one semiconductor device, specifically a power semiconductor device. The power switch may be or may comprise at least one electronic circuit, specifically at least one integrated circuit. The power switch may specifically comprise at least one transistor. The transistor may be selected from the group consisting of: a field-effect transistor (FET), specifically a metal-oxide field-effect transistor (MOSFET); a bipolar transistor; an insulated-gate bipolar transistor (IGBT). Other options may also be feasible.

The power switch may be a smart power switch or an intelligent power switch, specifically an intelligent protected power switch. Thus, the power switch may be configured for performing further tasks apart from pure switching operations. The power switch may be configured for communicating with further devices, specifically with the controller. The power switch may comprise an interface. The power switch may comprise at least one pin. The power switch may comprise a logic circuit configured for processing signals, specifically the diagnosis control signal from the controller. The logic circuit may comprise at least one logic gate, e.g. an OR gate. The power switch may be configured for performing a measurement. The power switch may comprise a measurement circuit. The measurement circuit may specifically at least be configured for sensing a current. The power switch may be configured for evaluating the measurement. The power switch may have different states, specifically different diagnosis states, wherein each state may refer to a different task, e.g. a current sense, as will also be outlined in further detail below.

The diagnosis states may be defined and/or stored in a memory. Specifically, the states may be defined and/or stored at different addresses in address register. More specifically, a setting of the power switch for each diagnosis state may be stored at an address in an address register of the power switch. The power switch may comprise a memory. The power switch may comprise an address register. The address register may be configured for storing the diagnosis states or more specifically the settings for each diagnosis state. Thus, retrieving addresses in the address register may cause the power switch to obtain different states. Thus, the sequential diagnosis may comprise stepping through or sweeping through different addresses, e.g. by using a counter, specifically a diagnosis state counter. The power switch may comprise at least one counter. Specifically, the diagnosis switch may comprise a diagnosis state counter. The diagnosis state counter may be configured for changing the diagnosis states. For such purpose, the diagnosis state counter may for instance increment an address value. The diagnosis state counter may be configured for changing an address, specifically an address defining a diagnosis state of the power switch.

The term “diagnosis state” as generally used herein is a broad term and is to be given its ordinary and customary meaning to a person of ordinary skill in the art and is not to be limited to a special or customized meaning. With respect to the diagnosis state, reference may also be made to the previous paragraphs for further details. A diagnosis state may refer to a specific task performed within a diagnosis, specifically within a sequential diagnosis comprising different sequentially performed tasks. As an example, the diagnosis state may be a current sense state. The diagnosis state may refer to a specific task performed by the power switch. The diagnosis state may specifically comprise a setting of the power switch, such as a measurement setting. As indicated above, each diagnosis state may be stored in an address at an address register of the power switch. Specifically, a setting of the power switch for each diagnosis state may be stored at an address in an address register of the power switch. The sequential diagnosis may be performed by, in normal operation, sequentially going through predetermined diagnosis states. Going through the diagnosis states may be achieved by using a diagnosis state counter which may sequentially increment an address for this purpose. In fault operation, the sequential diagnosis may be reset. Correspondingly, the diagnosis state counter may be reset in such an event. The diagnosis state counter may specifically respond to a diagnosis control signal from the controller and more specifically to timeouts in the diagnosis control signal.

The term “diagnosis control signal” as generally used herein is a broad term and is to be given its ordinary and customary meaning to a person of ordinary skill in the art and is not to be limited to a special or customized meaning. The diagnosis control signal may be a signal controlling a diagnosis state or a change of the diagnosis state. Specifically, the diagnosis control signal may be a signal sent from the controller to the power switch for controlling a diagnosis state or a change of the diagnosis state of the power switch. A change of the diagnosis state may specifically be changed by using timeouts of the diagnosis control signal, as will be described in further detail below. The diagnosis control signal may be a digital signal, specifically a binary signal. The diagnosis control signal may comprise signal states HIGH and LOW. HIGH may refer to a predetermined high voltage. LOW may refer to a predetermined low voltage. Specifically, HIGH may be a distinguishably higher voltage than LOW. HIGH may correspond to a logical 1 in binary representation. LOW may correspond to a logical 0 in binary representation. A timeout of the diagnosis control signal may be a LOW time of the diagnosis control signal. Alternatively, a timeout of the diagnosis control signal may be an interruption, specifically a temporal interruption, of the diagnosis control signal. Other options may also be feasible.

In a step b), the method comprises, if a timeout matches a predetermined time interval, continuing the sequential diagnosis by going on to a subsequent diagnosis state of the present diagnosis state. Thus, if the timeout of the diagnosis control signal matches a predetermined time interval, a present diagnosis state of the power switch may be changed to a subsequent diagnosis state of the sequential diagnosis. As an example, the time interval may be 25 μs to 150 μs. In a step c), the method comprises, if a timeout exceeds a predetermined time threshold, resetting the sequential diagnosis by restarting at the initial diagnosis state. This feature may be used for restarting the method at a defined diagnosis state, e.g. in case of a loss of synchronization. Thus, if a timeout of the diagnosis control signal exceeds a predetermined time threshold, the sequential diagnosis may be restarted again. Exceeding the time threshold may comprise at least one of going above an upper time threshold and going below a lower time threshold. Thus, exceeding the time threshold may comprise exceeding or going above an upper time threshold. As an example, the upper time threshold may be more than or equal to 150 μs. Additionally or alternatively, exceeding the time threshold may comprise exceeding or going below a lower time threshold. As an example, the lower time threshold may be less than or equal to 25 μs.

At least one of the diagnosis states, a sequence of the diagnosis states, the time interval and the time threshold, specifically the upper time threshold and/or the lower time threshold, may be defined in a protocol. The protocol may be a communication protocol implemented in the power network for communication between at least the controller and the power switch. As said, the power switch may be a smart power switch. Thus, the power which may be configured for understanding or interpreting the protocol, such as by using a logic circuit. The logic circuit may specifically be configured for processing the diagnosis state signal, specifically for the diagnosis state counter. As also said, the power switch may comprise a diagnosis state counter. The diagnosis state counter may be connected to the logic circuit. The diagnosis state counter may be configured for responding to the diagnosis state signal processed by the logic circuit. The diagnosis state counter may be configured for setting a diagnosis state of the power switch. Step b) may comprise increasing or incrementing the diagnosis state counter, specifically to a subsequent address in an address register of the power switch. Step c) may comprise resetting or restarting the diagnosis state counter, specifically to an initial address at which the sequential diagnoses was initially started.

In a step d), the method may further comprise, if the timeout is interrupted by at least two signal edges, resetting the sequential diagnosis by restarting at the initial diagnosis state. Thus, if two signal edges are sent from the controller to the power switch, the sequential diagnosis may also be restarted. A signal edge may be short HIGH time of the diagnosis control signal, such as HIGH time of for instance 10 μs or less. In a step e), the method may further comprise, otherwise, continuing the sequential diagnosis by remaining at the present diagnosis state. Specifically, in step e), the method may comprise, if neither the timeout matches a predetermined time interval, nor the timeout exceeds a predetermined time threshold, continuing the sequential diagnosis by remaining at the present diagnosis state. More specifically, in step e), the method may comprise, if neither the timeout matches a predetermined time interval, nor the timeout exceeds a predetermined time threshold, nor the timeout is interrupted by at least two signal edges, continuing the sequential diagnosis by remaining at the present diagnosis state. As an example, the time interval may be 25 μs to 150 μs, the time threshold may be an upper time threshold of 150 μs, there may be no lower time threshold and the timeout may also not be interrupted by signal edges. In such case, if the timeout is lower than 25 μs, the sequential diagnosis may then be continued by remaining at a present diagnosis state according to step e). Other implementation options may of course also be feasible.

In a step f), the method may further comprise, for each present diagnosis state, sending a diagnosis state signal from the power switch to the controller. The term “diagnosis state signal” as generally used herein is a broad term and is to be given its ordinary and customary meaning to a person of ordinary skill in the art and is not to be limited to a special or customized meaning. The diagnosis state signal may be a signal referring to a specific diagnosis state of the power switch. The diagnosis state signal may be indicative of a result of a task performed by the power switch in a specific diagnosis state. As an example, the diagnosis state may be a current sense state and the diagnosis state signal may refer to the sensed current. The diagnosis state signal may comprise a status value. The diagnosis state signal may comprise a current sense signal or a signal derived thereof, specifically a signal referring to a derived energy value, more specifically to a i²t value. The i²t value, in German also referred to as “Grenzlastintegral” or “Schmelzintegral”, may generally refer to an integration of the squared current over time. An energy absorbed by an electronic component over time may be a function of the i²t value. A temperature increase of the electronic component may again be a function of the absorbed energy. An overtemperatures or an overcurrent may damage or destroy the electronic component. Thus, the i²t value or the current sense signal may be indicative for an overtemperature or an overcurrent. Thus, the i²t value or the current sense signal may be used as an indicator for switching off a load before damaging the load. In a step g), the method may further comprise, if the diagnosis state signal indicates an overcurrent, switching off a load by using the power switch. In other words, the load may be disconnected from a power supply in such case, such as by opening the power switch.

Throughout the present disclosure, the presented method steps may be performed in the indicated order. It shall be noted, however, that a different order may also be possible. The method may comprise further method steps which are not listed. Further, one or more of the method steps may be performed once or repeatedly. Further, two or more of the method steps may be performed simultaneously or in a timely overlapping fashion. The power switch may comprise at least two pins, specifically a diagnosis enable (DEN) pin and a current sense (IS) pin. Steps a) to c) and optionally steps d) and e) may be performed by using a first pin of the power switch, specifically the DEN pin. Step f) may be performed by using a separate second pin of the power switch, specifically the IS pin. Thus, the diagnosis control signal may be sent or transmitted from the controller to the power switch via the DEN pin, e.g. from a general purpose input/output (GPIO) pin of the controller. Thus, the first pin, specifically the DEN pin, may be configured for receiving the diagnosis control signal from the controller. The controller may comprise a GPIO pin. The GPIO pin may be configured for sending the diagnosis control signal. Further, the diagnosis state signal may be transmitted or sent from the power switch via the IS pin to the controller, e.g. to an analog-to-digital converter (ADC) of the controller. Thus, the second pin, specifically the IS pin, may be configured for sending or transmitting the diagnosis state signal to the controller. The controller may comprise an ADC. The ADC may be configured for receiving the diagnosis state signal. Generally, the power network may comprise an interconnection. The interconnection may connect at least the controller and the power switch. Thus, the interconnection may further connect at least one of the controller and the power switch to at least one further device. The interconnection may be a wired interconnection. The interconnection may comprise a plurality of signal lines, e.g. wires or traces. The diagnosis control signals, and optionally the diagnosis control signals, may be sent or transmitted between the controller and the power switch via the interconnection.

In a further aspect, a power network is presented. The power network comprises at least a power switch for switching a load and a controller for controlling the power switch. The controller may be configured for controlling further devices besides the power switch, such as further power switches and/or other kinds of devices. Thus, the controller may specifically be configured for controlling a plurality of power switches. The controller is configured for sending a diagnosis control signal to the power switch for starting a sequential diagnosis at an initial diagnosis state of the power switch. The controller is further configured for using timeouts of the diagnosis control signal for changing a present diagnosis state of the power switch. The power switch is configured for, if a timeout matches a predetermined time interval, continuing the sequential diagnosis by going on to a subsequent diagnosis state of the present diagnosis state. The power switch is further configured for, if a timeout exceeds a predetermined time threshold, resetting the sequential diagnosis by restarting at the initial diagnosis state.

Generally, the controller and the power switch may be configured for performing a sequential diagnosis in the power network according to any one of the embodiments referring to a method for performing a sequential diagnosis in a power network as described above or below in further detail. Specifically, the power switch may further be configured for, if the timeout is interrupted by at least two signal edges, resetting the sequential diagnosis by restarting at the initial diagnosis state. The power switch may further be configured for otherwise continuing the sequential diagnosis by remaining at the present diagnosis state. Specifically, the power switch may be configured for, if neither the timeout matches a predetermined time interval, nor the timeout exceeds a predetermined time threshold, continuing the sequential diagnosis by remaining at the present diagnosis state. More specifically, the power switch may be configured for, if neither the timeout matches a predetermined time interval, nor the timeout exceeds a predetermined time threshold, nor the timeout is interrupted by at least two signal edges, continuing the sequential diagnosis by remaining at the present diagnosis state. The power switch may further be configured for, for each present diagnosis state, sending a diagnosis state signal from the power switch to the controller. The power switch may be configured for, if the diagnosis state signal indicates an overcurrent, switching off the load. For further definitions and embodiments regarding the power network reference may be made to the definitions and embodiments regarding the method for performing a sequential diagnosis in a power network given above.

The methods and devices presented herein have considerable advantages over the prior art as already indicated throughout the description. Controlling a diagnosis state of the power switch by using timeouts in the diagnosis control signal may simplify the sequential diagnosis and make it more robust. Specifically, the reset may be simplified and controlled by using only one signal, i.e. the diagnosis state signal instead of using one or more further signals for this purpose. This may additionally save one or more further pins at the devices. Controlling multiple pins synchronously during application is typically impossible or at least difficult. Now, the further pins may solely be used for other purposes. Thus, by using the presented methods and devices, the reset may now specifically be independent from additional pins.

As used herein, the terms “have”, “comprise” or “include” or any arbitrary grammatical variations thereof are used in a non-exclusive way. Thus, these terms may both refer to a situation in which, besides the feature introduced by these terms, no further features are present in the entity described in this context and to a situation in which one or more further features are present. As an example, the expressions “A has B”, “A comprises B” and “A includes B” may both refer to a situation in which, besides B, no other element is present in A (i.e. a situation in which A solely and exclusively consists of B) and to a situation in which, besides B, one or more further elements are present in entity A, such as element C, elements C and D or even further elements.

Further, it shall be noted that the terms “at least one”, “one or more” or similar expressions indicating that a feature or element may be present once or more than once typically are used only once when introducing the respective feature or element. In most cases, when referring to the respective feature or element, the expressions “at least one” or “one or more” are not repeated, nonwithstanding the fact that the respective feature or element may be present once or more than once.

Further, as used herein, the terms “preferably”, “more preferably”, “particularly”, “more particularly”, “specifically”, “more specifically” or similar terms are used in conjunction with optional features, without restricting alternative possibilities. Thus, features introduced by these terms are optional features and are not intended to restrict the scope of the claims in any way. The disclosure may, as the skilled person will recognize, be performed by using alternative features. Similarly, features introduced by “in an embodiment of the disclosure” or similar expressions are intended to be optional features, without any restriction regarding alternative embodiments of the disclosure, without any restrictions regarding the scope of the disclosure and without any restriction regarding the possibility of combining the features introduced in such way with other optional or non-optional features of the disclosure.

Summarizing and without excluding further possible embodiments, the following Embodiments may be envisaged:

Embodiment 1: A method for performing a sequential diagnosis in a power network, the method comprising:
a) sending a diagnosis control signal from a controller to a power switch for starting the sequential diagnosis at an initial diagnosis state of the power switch and using timeouts of the diagnosis control signal for changing a present diagnosis state of the power switch;
b) if a timeout matches a predetermined time interval, continuing the sequential diagnosis by going on to a subsequent diagnosis state of the present diagnosis state; and
c) if a timeout exceeds a predetermined time threshold, resetting the sequential diagnosis by restarting at the initial diagnosis state.

Embodiment 2: The method according to the preceding Embodiment, wherein the power network is an automotive power network, specifically a distributed automotive power network.

Embodiment 3: The method according to any one of the preceding Embodiments, wherein the method is performed in an automotive power network, specifically in a distributed automotive power network.

Embodiment 4: The method according to any one of the preceding Embodiments, wherein exceeding the time threshold in step c) comprises at least one of going above an upper time threshold and going below a lower time threshold.

Embodiment 5: The method according to the preceding Embodiment, wherein the upper time threshold is more than or equal to 150 μs.

Embodiment 6: The method according to any one of the two preceding Embodiments, wherein the lower time threshold is less than or equal to 25 μs.

Embodiment 7: The method according to any one of the preceding Embodiments, wherein the time interval in step b) is 25 μs to 150 μs.

Embodiment 8: The method according to any one of the preceding Embodiments, further comprising:
d) if the timeout is interrupted by at least two signal edges, resetting the sequential diagnosis by restarting at the initial diagnosis state.

Embodiment 9: The method according to any one of the preceding Embodiments, further comprising:
e) otherwise continuing the sequential diagnosis by remaining at the present diagnosis state.

Embodiment 10: The method according to any one of the preceding Embodiments, wherein the diagnosis control signal is a digital signal, specifically a binary signal.

Embodiment 11: The method according to the preceding Embodiment, wherein the diagnosis control signal comprises signal states HIGH and LOW, wherein a timeout of the diagnosis control signal is a LOW time of the diagnosis control signal.

Embodiment 12: The method according to any one of the preceding Embodiments, wherein at least one of the diagnosis states, a sequence of the diagnosis states, the time interval and the time threshold are defined in a protocol.

Embodiment 13: The method according to any one of the preceding Embodiments, wherein a setting of the power switch for each diagnosis state is stored at an address in an address register of the power switch.

Embodiment 14: The method according to any one of the preceding Embodiments, wherein the power switch comprises a diagnosis state counter configured for setting a diagnosis state of the power switch, wherein step b) comprises increasing the diagnosis state counter, wherein step c) comprises resetting the diagnosis state counter.

Embodiment 15: The method according to any one of the preceding Embodiments, further comprising:
f) for each present diagnosis state, sending a diagnosis state signal from the power switch to the controller.

Embodiment 16: The method according to the preceding Embodiment, wherein the diagnosis state signal comprises a current sense signal or a signal derived thereof, specifically a signal referring to a derived energy value, more specifically to a i²t value.

Embodiment 17: The method according to any one of the two preceding Embodiments, further comprising:
g) if the diagnosis state signal indicates an overcurrent, switching off a load by using the power switch.

Embodiment 18: The method according to any one of the three preceding Embodiments, wherein steps a) to c), and optionally steps d) and e), are performed by using a first pin of the power switch, wherein step f) is performed by using a separate second pin of the power switch.

Embodiment 19: The method according to any one of the preceding Embodiments, wherein the power network comprises an interconnection, wherein the diagnosis control signals, and optionally the diagnosis state signals, are sent between the controller and the power switch via the interconnection.

Embodiment 20: A power network comprising at least a power switch for switching aload and a controller for controlling the power switch, wherein the controller is configured for sending a diagnosis control signal to the power switch for starting a sequential diagnosis at an initial diagnosis state of the power switch, wherein the controller is further configured for using timeouts of the diagnosis control signal for changing a present diagnosis state of the power switch, wherein the power switch is configured for, if a timeout matches a predetermined time interval, continuing the sequential diagnosis by going on to a subsequent diagnosis state of the present diagnosis state, wherein the power switch is further configured for, if a timeout exceeds a predetermined time threshold, resetting the sequential diagnosis by restarting at the initial diagnosis state.

Embodiment 21: The power network according to the preceding Embodiment, wherein the power network is an automotive power network, specifically a distributed automotive power network.

Embodiment 22: The power network according to any one of the preceding Embodiments referring to a power network, wherein the controller is a zone controller.

Embodiment 23: The power network according to any one of the preceding Embodiments referring to a power network, wherein the controller is a microcontroller.

Embodiment 24: The power network according to any one of the preceding Embodiments referring to a power network, wherein the power switch is further configured for, if the timeout is interrupted by at least two signal edges, resetting the sequential diagnosis by restarting at the initial diagnosis state.

Embodiment 25: The power network according to any one of the preceding Embodiments referring to a power network, wherein the power switch is further configured for otherwise continuing the sequential diagnosis by remaining at the present diagnosis state.

Embodiment 26: The power network according to any one of the preceding Embodiments referring to a power network, wherein the power switch is further configured for, for each present diagnosis state, sending a diagnosis state signal from the power switch to the controller.

Embodiment 27: The power network according to the preceding Embodiment, wherein the controller comprises an analog-to-digital converter (ADC) configured for receiving the diagnosis state signal, specifically the current sense signal.

Embodiment 28: The power network according to the preceding Embodiment, wherein the power switch is configured for, if the diagnosis state signal indicates an overcurrent, switching off the load.

Embodiment 29: The power network according to any one of the preceding Embodiments referring to a power network, wherein the controller and the power switch are configured for performing a sequential diagnosis in the power network according to any one of the preceding method Embodiments.

Embodiment 30: The power network according to any one of the preceding Embodiments referring to a power network, wherein the power switch is a smart power switch.

Embodiment 31: The power network according to any one of the preceding Embodiments referring to a power network, wherein the power switch comprises a logic circuit configured for processing the diagnosis control signal.

Embodiment 32: The power network according to any one of the preceding Embodiments referring to a power network, wherein the power switch comprises an address register configured for storing the diagnosis states.

Embodiment 33: The power network according to any one of the preceding Embodiments referring to a power network, wherein the power switch comprises a diagnosis state counter configured for changing the diagnosis states.

Embodiment 34: The power network according to any one of the preceding Embodiments referring to a power network, wherein the power switch comprises a measurement circuit configured for sensing a current.

Embodiment 35: The power network according to any one of the preceding Embodiments referring to a power network, wherein the power switch comprises at least two pins.

Embodiment 36: The power network according to the preceding Embodiment, wherein a first pin is configured for receiving the diagnosis control signal from the controller.

Embodiment 37: The power network according to any one of the two preceding Embodiments, wherein a second pin is configured for sending the diagnosis state signal to the controller.

Embodiment 38: The power network according to any one of the preceding Embodiments referring to a power network, wherein the power switch comprises a transistor selected from the group consisting of: a field-effect transistor (FET), specifically a metal-oxide field-effect transistor (MOSFET); a bipolar transistor; an insulated-gate bipolar transistor (IGBT).

Embodiment 39: The power network according to any one of the preceding Embodiments referring to a power network, further comprising an interconnection connecting the controller and the power switch.

Embodiment 40: The power network according to any one of the preceding Embodiments referring to a power network, wherein the controller comprises at least one pin, specifically a general-purpose input/output (GPIO) pin, configured for sending the diagnosis control signal.

Further optional features and embodiments will be disclosed in more detail in the subsequent description of embodiments, preferably in conjunction with the dependent embodiments. Therein, the respective optional features may be realized in an isolated fashion as well as in any arbitrary feasible combination, as the skilled person will realize. The scope of the disclosure is not restricted by the preferred embodiments. The embodiments are schematically depicted in the Figures. Therein, identical reference numbers in these Figures refer to identical or functionally comparable elements.

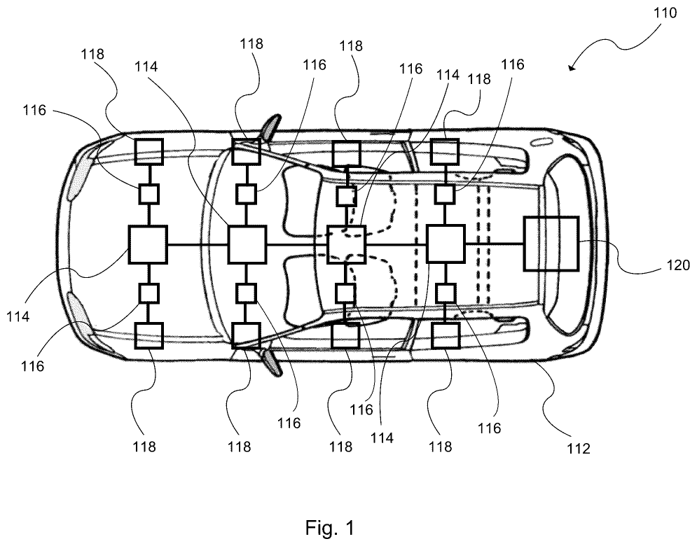

FIG. 1 illustrates an exemplary embodiment of a power network 110, specifically of an automotive power network 110, more specifically of a distributed automotive power network 110. Thus, the power network 110 may be distributed within an automobile 112. As a result, the power network 110 may be configured for spatially distributing electrical power within the automobile 112. Said distribution may be controlled by several electronic components of the power network. The power network 110 comprises at least a controller 114 and a power switch 116. The controller 114 is configured for controlling the power switch 116. The power switch 116 is configured for switching a load 118. Thus, the controller 114 may at least indirectly be configured for controlling the load 118. In an automotive application, the load 118 may specifically comprise a motor. As shown, the power network 110 may specifically comprise a plurality of controllers 114 and power switches 116 and loads 118. Each controller 114 may be configured for controlling a plurality of power switches 116. The controller 114 may specifically be a microcontroller. The controller 114 may specifically be a zone controller 114. Thus, the controller 114 may be configured for controlling one or more power switches 116 in a specific area of the automobile 112, e.g. in a back area of the automobile 112. The power network 110 may further comprise a power supply 120. In an automotive application, the power supply 120 may specifically be a battery. The controller 114 and/or the power switch 116 may be configured for distributing electrical power within the power network 110, specifically electrical power provided by the power supply 120.

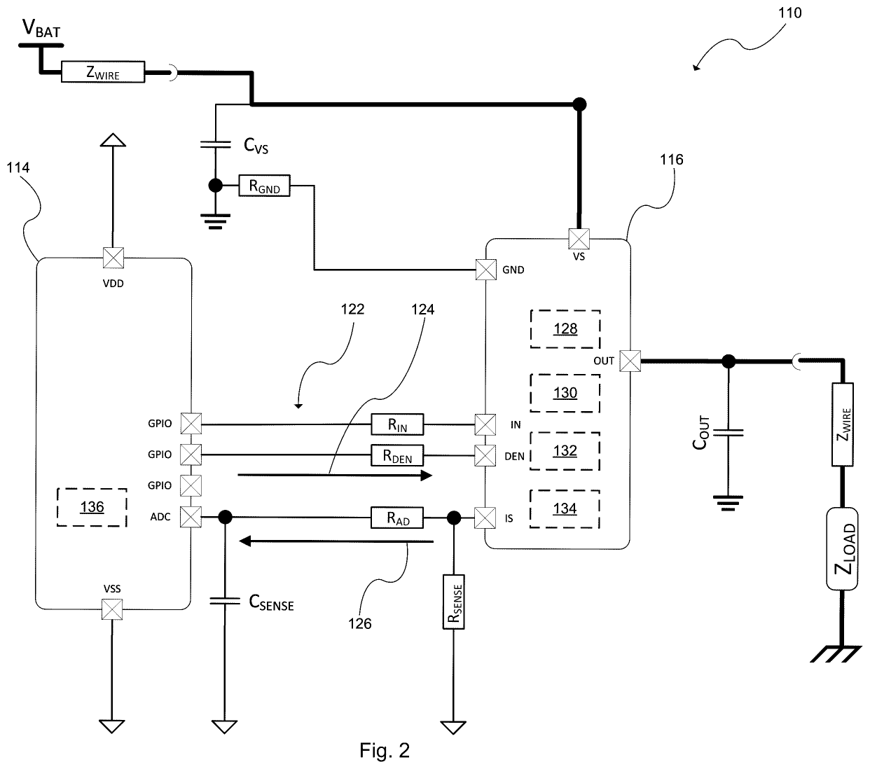

FIG. 2 illustrates a circuit diagram of an exemplary embodiment of the power network 110. As said, the power network 110 specifically comprises the controller 114 and the power switch 116. Further, the power network 110 may comprise an interconnection 122 connecting controller 114 and the power switch 116. The interconnection 122 may comprise a plurality of signal lines, e.g. wires or traces, connecting pins of the controller 114 and the power switch 116. The controller 114 may comprise at least one of an GPIO pin and an ADC pin. Specifically, the controller 114 may comprise a plurality of GPIO pins. The power switch 116 may comprise at least one of an input (IN) pin and an output (OUT) pin. The IN pin may be connected to the controller 114. The OUT pin may be connected to the load 118. Further, the power switch 116 may comprise a supply voltage (VS) pin. The VS pin may be connected to the power supply 120, which may as said specifically be a battery providing a battery voltage V_{BAT}. The controller 114 may for instance send a pulse width modulation signal to the IN pin for controlling a switching behavior of the power switch. Correspondingly, the power switch 116 may connect the load 118 to the power supply 120 or disconnect the load 118 from the power supply 120 and thereby switch the load 118 on and off, respectively. Thus, V_{BAT} may be transferred to the load 118 via the OUT pin. The power switch 116 may specifically comprise a transistor as switching element for such purpose. The transistor may be selected from the group consisting of: a FET, specifically a MOSFET; a bipolar transistor; an IGBT. Other options may also be feasible.

The power switch 116 may be a smart power switch 116 or an intelligent power switch 116. The power switch 116 may specifically further comprise at least one of a DEN pin and an IS pin. The power switch 116 may be configured for exchanging diagnosis signals with the controller 114 via the interconnection 122. Likewise, the controller 114 may be configured for exchanging diagnosis signals with the power switch 116 via the interconnection 122. Specifically, the power switch 116 and the controller 114 may be configured for exchanging diagnosis signals between the DEN pin and a GPIO pin and/or between the IS pin and the ADC pin as shown in FIG. 2. The diagnosis signals may comprise diagnosis control signals and/or diagnosis state signals. Thus, a diagnosis control signal may be sent from the controller 114 via a GPIO pin, the interconnection 122 and the DEN pin to the power switch 116. A diagnosis state signal may be sent from the power switch 116 via the IS pin, the interconnection 122 and the ADC pin to the controller 114. A progression of the diagnosis control signal is indicated by arrow 124 in FIG. 2 and progression of the diagnosis state signal is indicated by arrow 126. Thus, the diagnosis signals, specifically the diagnosis control signals, may not be sent via the IN pin of the power switch. The diagnosis, which may specifically be a sequential diagnosis, may be independent from the IN pin and there may in consequence be no limitations for e.g. pulse width modulation signals sent from the controller 114 via the IN pin to the power switch 116.

Thus, the power switch 116 may be configured for performing a diagnosis, specifically a sequential diagnosis, at least in cooperation with the controller 114. The power switch 116 may comprise a logic circuit 128. The logic circuit 128 may be configured for processing the diagnosis control signal, specifically timeouts of the diagnosis control signal as will also be described in further detail below. The power switch 116, specifically the logic circuit 128 may be configured for evaluating the timeouts, specifically a length of the timeouts. The logic circuit 128 may further generally be configured for enabling the power switch 116 to communicate with the controller 114. The power switch 116 may comprise an address register 130. The address register 130 may comprise a plurality of addresses. The address register 130 may also generally be configured for enabling the power switch 116 to communicate with the controller 114. Specifically, an address may also represent a diagnosis state of the power switch 116 within a sequential diagnosis. Additionally or alternatively, an address may represent a setting of a diagnosis state of the power switch 116. As an example, the diagnosis state may be a current sense state. Thus, the address register 130 may be configured for storing the diagnosis states or settings of the diagnosis states.

In the sequential diagnosis, the power switch 116 may sweep through or step through different predetermined diagnosis states. The sweeping may specifically be triggered by the diagnosis control signal from the controller 114. More specifically, the sweeping may be triggered by timeouts in the diagnosis control signal, as will be explained in further detail below. In each diagnosis state, the power switch 116 may then respond to the controller via the diagnosis control signal. As an example, the diagnosis control signal may be or may comprise a current sense signal or a signal derived thereof. The sweeping through the diagnosis states may specifically be realized by using a counter. The power switch 116 may comprise a diagnosis state counter 132 for such purpose. The diagnosis state counter 132 may be configured for changing the diagnosis state of the power switch 116. Specifically, the diagnosis state counter 132 may be configured for sweeping through the diagnosis states by incrementing an address value in the address register of the power switch 116. Thus, the sequential diagnosis may comprise sweeping through a plurality of diagnosis states by using the diagnosis state counter 132. The diagnosis state counter 132 may further be resettable. Thus, instead of continuing with a subsequent diagnosis state in the address register, the power switch 116 may go into an initial diagnosis state of the sequential diagnosis again and restart the sequential diagnosis.

As already indicated, a diagnosis state of the power switch 116 may for instance be a current sense state. Thus, the diagnosis state signal may for instance be a current sense signal or a signal derived thereof. The power switch 116 may be a protected power switch 116. In case of an overcurrent, or also in other failure events, the power switch 116 may be configured for switching off the load 118. Thus, the power switch 116 may be configured for observing or monitoring the current. Thus, the power switch 116 may comprise a measurement circuit 134 for sensing or measuring the current and for generating a corresponding current sense signal as diagnosis state signal. The controller 114 may comprise an ADC 136. The ADC 136 may generally be configured for receiving and processing the diagnosis state signal, which may as said specifically be a current sense signal. Specifically, the diagnosis state signal, more specifically the current sense signal, may be transferred into a voltage by using a resistor R_{SENSE}. Said voltage may then be read out by the controller 114 by using the ADC 136. Overall, the controller 114 and the power switch 116 may specifically by configured for performing a sequential diagnosis in the power network 110 as will be described in the following.

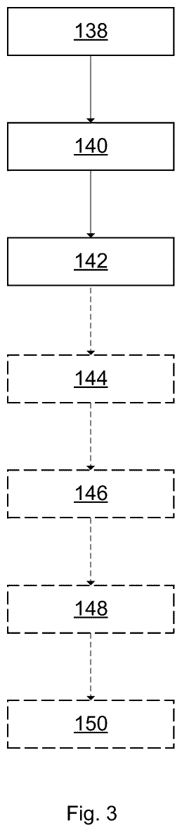

FIG. 3 illustrates a flow chart of an exemplary embodiment of a method for performing a sequential diagnosis in the power network 110. The method comprises the following steps:
a) (denoted by reference numeral 138) sending a diagnosis control signal from the controller 114 to the power switch 116 for starting the sequential diagnosis at an initial diagnosis state of the power switch 116 and using timeouts of the diagnosis control signal for changing a present diagnosis state of the power switch 116;
b) (denoted by reference numeral 140) if a timeout matches a predetermined time interval, continuing the sequential diagnosis by going on to a subsequent diagnosis state of the present diagnosis state; and
c) (denoted by reference numeral 142) if a timeout exceeds a predetermined time threshold, resetting the sequential diagnosis by restarting at the initial diagnosis state.

The method may further comprise one or more of the following steps:
d) (denoted by reference numeral 144) if the timeout is interrupted by at least two signal edges, resetting the sequential diagnosis by restarting at the initial diagnosis state;
e) (denoted by reference numeral 146) otherwise continuing the sequential diagnosis by remaining at the present diagnosis state;
f) (denoted by reference numeral 148) for each present diagnosis state, sending a diagnosis state signal from the power switch 116 to the controller 114; and
g) (denoted by reference numeral 150) if the diagnosis state signal indicates an overcurrent, switching off the load 118 by using the power switch 116.

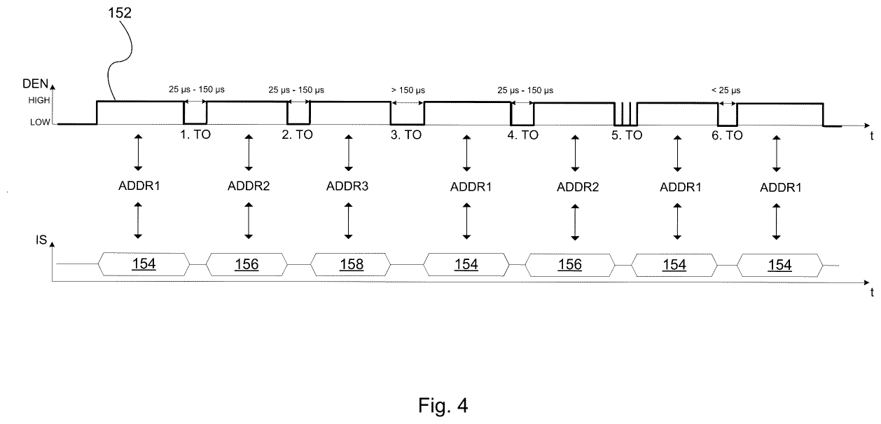

FIG. 4. illustrates a further flow chart indicating an exemplary sequence of diagnosis states in a sequential diagnosis. As indicated, the diagnosis control signal may be sent from the controller 114 via the DEN PIN to the power switch 116 for controlling the diagnosis state of the power switch 116. An exemplary timeline of the diagnosis control signal is indicated by reference numeral 152 in FIG. 4. The diagnosis control signal may be a digital signal, specifically a binary signal. Thus, the control signal may comprise signal states HIGH and LOW. A timeout of the diagnosis control signal may be a LOW time of the diagnosis control signal. The sequential diagnosis may start at an initial or first diagnosis state of the power switch 116. The first diagnosis state may correspond to a first address ADDR1 in the address register 130 of the power switch 116. Corresponding to the first diagnosis state, the power switch 116 may send a first diagnosis state signal via the IS pin to the controller 114. A timeline of a diagnosis state signal corresponding to the first diagnosis state is indicated by reference numeral 154 in FIG. 4. Generally, the diagnosis state signal may comprise a current sense signal or a signal derived thereof, specifically a signal referring to a derived energy value, more specifically to a i²t value. The diagnosis state signal may be or may comprise an analog signal or a digital signal. The diagnosis state signal may be or may comprise a data package or a message.

A first timeout, indicated as 1. TO in FIG. 4, may be within the time interval referred to in step b), e.g. between 25 μs and 150 μs. Thus, the diagnosis state counter 132 may increment the present address ADDR1 to subsequent address ADDR2 in the address register 130 of the power switch 116. Accordingly, the power switch 116 may take on a second diagnosis state and send a corresponding second diagnosis state signal to the controller 114. A timeline of a diagnosis state signal corresponding to the second diagnosis state is indicated by reference numeral 156 in FIG. 4. A second timeout, indicated as 2. TO in FIG. 4, may again be within the time interval referred to in step b), such that the diagnosis state counter 132 may increment the present address ADDR2 to subsequent address ADDR3 representing a third diagnosis state. In the third diagnosis state, the power switch 116 may send a corresponding third diagnosis state signal to the controller 114. A timeline of a diagnosis state signal corresponding to the third diagnosis state is indicated by reference numeral 158 in FIG. 4.

Subsequently, the diagnosis state counter 132, and the sequential diagnosis overall, may be reset, e.g. because the controller 114 lost synchronization of the present address. This may be achieved by using a third timeout of the diagnosis control signal exceeding a predetermined time threshold as outlined in step c). The third timeout is indicated as 3. TO in FIG. 4. Exceeding the time threshold referred to in step c) may generally comprise going above an upper time threshold and/or going below a lower time threshold. As an example and as indicated in FIG. 4, the predetermined time threshold may be an upper time threshold of 150 μs and the third timeout may be longer than said 150 μs. Thus, the diagnosis state counter 132 may be reset to initial address ADDR1 again for restarting the sequential diagnosis at a known address and at the initial first diagnosis state. Thus, the power switch 116 may again send the first diagnosis state signal or an updated version thereof to the controller 114. More generally, the power switch 116 may again send a diagnosis state signal corresponding to the first diagnosis state of the power switch 116 to the controller 114. A fourth timeout, indicated as 4. TO in FIG. 4, may again be in the time interval referred to in step b), e.g. between 25 μs and 150 μs, such that the sequential diagnosis may proceed with a subsequent diagnosis state stored at ADDR2 in the address register 130 of the power switch 116.

A fifth timeout, indicated as 5. TO in FIG. 4, may be interrupted by two signal edges. This may also be used for restarting the sequential diagnosis at the initial diagnosis state as referred to in step d). Thus, the power switch 116 may send a diagnosis state signal corresponding to the first diagnosis state again. A sixth timeout, indicated as 6. TO in FIG. 4, may neither be in the predetermined time interval referred to in step b), nor above the predetermined upper time threshold referred to in step c), nor may it comprise interrupting signal edges as referred to in step d). In such case, the diagnosis state counter 132 may remain at the present address, i.e. ADDR 1 here, as referred to in step e). Thus, the power switch 116 may resend the last diagnosis state signal or an updated version thereof to the controller 114. In the present example, the power switch 116 may send a diagnosis state signal corresponding to the first diagnosis state once more. Other values for the time threshold or the time interval or the number of signal edges interrupting the timeout may of course also be possible. Generally, the predetermined time threshold or the predetermined time interval or also the exact settings for the diagnosis states as well as a sequence of the diagnosis states may be defined in a protocol.

Although specific examples have been illustrated and described herein, it will be appreciated by those of ordinary skill in the art that a variety of alternate and/or equivalent implementations may be substituted for the specific examples shown and described without departing from the scope of the present disclosure. This application is intended to cover any adaptations or variations of the specific examples discussed herein. Therefore, it is intended that this disclosure be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the disclosure and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the disclosure, as well as specific examples thereof, are intended to encompass equivalents thereof.

1. A method for performing a sequential diagnosis in a power network, the method comprising:
a) sending a diagnosis control signal from a controller to a power switch for starting the sequential diagnosis at an initial diagnosis state of the power switch and using timeouts of the diagnosis control signal for changing a present diagnosis state of the power switch;
b) if a timeout matches a predetermined time interval, continuing the sequential diagnosis by going on to a subsequent diagnosis state of the present diagnosis state; and
c) if a timeout exceeds a predetermined time threshold, resetting the sequential diagnosis by restarting at the initial diagnosis state.

2. The method of claim 1, wherein the method is performed in an automotive power network, specifically in a distributed automotive power network.

3. The method of claim 1, wherein exceeding the time threshold in step c) comprises at least one of going above an upper time threshold and going below a lower time threshold.

4. The method of claim 1, further comprising:
d) if the timeout is interrupted by at least two signal edges, resetting the sequential diagnosis by restarting at the initial diagnosis state.

5. The method of claim 4, further comprising:
e) otherwise, continuing the sequential diagnosis by remaining at the present diagnosis state.

6. The method of claim 1, wherein at least one of the diagnosis states, a sequence of the diagnosis states, the time interval and the time threshold are defined in a protocol.

7. The method of claim 1, wherein a setting of the power switch for each diagnosis state is stored at an address in an address register of the power switch.

8. The method of claim 1, wherein the power switch comprises a diagnosis state counter configured for setting a diagnosis state of the power switch, wherein step b) comprises increasing the diagnosis state counter, wherein step c) comprises resetting the diagnosis state counter.

9. The method of claim 1, further comprising:
f) for each present diagnosis state, sending a diagnosis state signal from the power switch to the controller.

10. The method of claim 1, wherein the diagnosis state signal comprises a current sense signal or a signal derived thereof, specifically a signal referring to a derived energy value, more specifically to a i²t value.

11. The method of claim 1, further comprising:
g) if the diagnosis state signal indicates an overcurrent, switching off a load by using the power switch.

12. A power network comprising at least a power switch for switching a load and a controller for controlling the power switch, wherein the controller is configured for sending a diagnosis control signal to the power switch for starting a sequential diagnosis at an initial diagnosis state of the power switch, wherein the controller is further configured for using timeouts of the diagnosis control signal for changing a present diagnosis state of the power switch, wherein the power switch is configured for, if a timeout matches a predetermined time interval, continuing the sequential diagnosis by going on to a subsequent diagnosis state of the present diagnosis state, wherein the power switch is further configured for, if a timeout exceeds a predetermined time threshold, resetting the sequential diagnosis by restarting at the initial diagnosis state.

13. The power network of claim 12, wherein the power network is an automotive power network, specifically a distributed automotive power network.

14. The power network of claim 12, wherein the controller is a zone controller.

15. The power network of claim 12, wherein the power switch is a smart power switch.

16. The power network of claim 12, wherein the power switch comprises a logic circuit configured for processing the diagnosis control signal.

17. The power network of claim 12, wherein the power switch comprises an address register configured for storing the diagnosis states.

18. The power network of claim 12, wherein the power switch comprises a diagnosis state counter configured for changing the diagnosis states.

19. The power network of claim 12, wherein the power switch comprises a measurement circuit configured for sensing a current.

20. The power network of claim 12, wherein the power switch comprises a transistor selected from the group consisting of: a field-effect transistor (FET), specifically a metal-oxide field-effect transistor (MOSFET); a bipolar transistor; an insulated-gate bipolar transistor (IGBT).
